(19) United States
(12) Patent Application Publication
(10) Pub. No.: US 2026/0075783 A1
(43) Pub. Date: Mar. 12, 2026

(54) DISPLAY DEVICE USED IN FRONT OF EYES OF USER

(71) Applicant: CANON KABUSHIKI KAISHA, Tokyo (JP)

(72) Inventors: TAKASHI TORII, Kanagawa (JP); HIROHITO KAI, Tokyo (JP)

(21) Appl. No.: 19/320,160

(22) Filed: Sep. 5, 2025

(30) Foreign Application Priority Data
Sep. 12, 2024 (JP) 2024-158197

(51) Int. Cl. H05K 7/20; G06F 1/16; G06F 1/20; H04N 13/239; H04N 13/344

(52) U.S. Cl. CPC H05K 7/20972; G06F 1/163; G06F 1/203; H04N 13/239; H04N 13/344; H04N 2213/001

(57) ABSTRACT

A display device includes two cameras that are arranged in a left-right direction and capture a front-surface side of the display device, a processing board, two displays that are arranged in the left-right direction and display images on a rear-surface side of the display device, a plurality of fans, and one or more inlet and outlet ports, wherein the processing board and the two cameras are disposed on the front-surface side with respect to the two displays, the plurality of fans are disposed on the front-surface side with respect to the processing board, the plurality of fans are disposed between the two cameras as viewed from the front-surface side, and a surface, on the rear-surface side, of each of the two cameras is disposed on the rear-surface side with respect to a surface, on the front-surface side, of each of the plurality of fans.

### BACKGROUND

### Field of the Technology

The present disclosure relates to a display device.

### Description of the Related Art

A head-mounted display (HMD), which is a display device used in front of eyes of a user, can provide virtual reality (VR) or mixed reality (MR) to the user. When the performance of the HMD is improved or a function of the HMD is increased, the power consumption of the HMD increases and a temperature of the HMD rises. In order to suppress the temperature rise of the HMD, a fan may be provided in the HMD.

Japanese Patent Laid-Open No. 2023-103349 discloses a layout of a fan.

However, the technique disclosed in Japanese Patent Laid-Open No. 2023-103349 cannot sufficiently consider a decrease in size of the HMD. It is preferable that the HMD is a display device used in front of the eyes of the user and decreases in size and weight. In a case where the size of the HMD is decreased, a size of a usable fan is also decreased. Generally, when the size of the fan is decreased, the cooling capability of the fan is low. Thus, it is difficult to achieve both decrease in size and high performance (including multi-functionality) of the HMD.

### SUMMARY

The present disclosure provides a display device such as an HMD that achieves both decrease in size and high performance (including multi-functionality).

A display device according to the present disclosure includes two cameras that are arranged in a left-right direction of the display device and capture a front-surface side of the display device, a processing board, two displays that are arranged in the left-right direction and display images on a rear-surface side of the display device, a plurality of fans, and one or more inlet and outlet ports, wherein the processing board and the two cameras are disposed on the front-surface side with respect to the two displays, the plurality of fans are disposed on the front-surface side with respect to the processing board, the plurality of fans are disposed between the two cameras as viewed from the front-surface side, and a surface, on the rear-surface side, of each of the two cameras is disposed on the rear-surface side with respect to a surface, on the front-surface side, of each of the plurality of fans.

Features of the present disclosure will become apparent from the following description of embodiments with reference to the attached drawings. The following description of embodiments is described by way of example.

### BRIEF DESCRIPTION OF THE DRAWINGS

FIG. 1 is an external view of a display device.

FIG. 2 is a sectional view of the display device.

FIG. 3 is a front view of the display device.

FIG. 4 is a rear view of the display device.

FIG. 5 is a bottom view of the display device.

FIG. 6 is a rear view of the display device.

FIG. 7 is a rear view of the display device.

FIG. 8 is a sectional view of the display device.

FIG. 9 is a diagram illustrating a fan.

### DESCRIPTION OF THE EMBODIMENTS

Hereinafter, an embodiment of the present disclosure will be described with reference to the accompanying drawings. Note that, the following embodiment does not limit the disclosure according to the claims. Although a plurality of features are described below, not all of the plurality of features are essential to the disclosure. The plurality of features may be voluntarily combined. Further, in the accompanying drawings, the same or similar components are denoted by the same reference numerals, and redundant description is omitted.

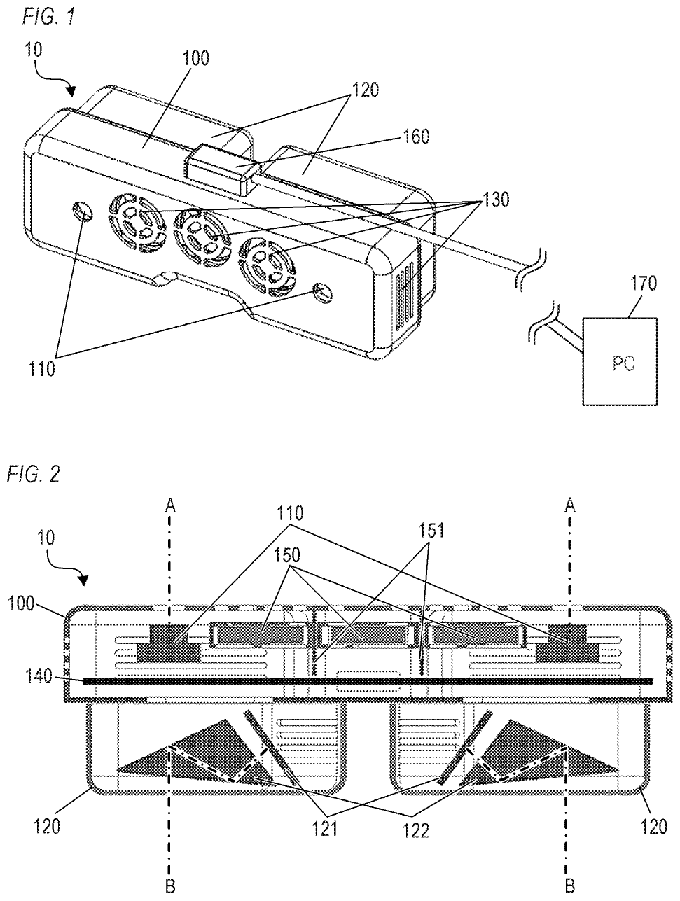

FIG. 1 is an external view of a display device 10 according to the present embodiment. In the present embodiment, the display device 10 is a head-mounted display (HMD), but the display device 10 is not limited to the HMD, and features of the present embodiment can be applied to various display devices to achieve the display device 10. The display device 10 includes two cameras 110 (imaging units), two display units 120, a housing 100, and a cable 160. The cable 160 may be detachably attached to the display device 10. A user disposes the display device 10 in front of eyes such that the two display units 120 are disposed in front of left and right two eyes, respectively. A left-right direction of the user in this state is a left-right direction of the display device 10, and an up-down direction of the user is an up-down direction of the display device 10. A surface of the display device 10 facing the user is a rear surface of the display device 10. Then, a surface of the display device 10 opposite to the rear surface of the display device 10 is a front surface of the display device 10. A side (direction) approaching the user (the user who disposes the display device 10 in front of the eyes) as viewed from a member is a rear-surface side of the display device 10 for the member, and a side (direction) moving away from the user as viewed from the member is a front-surface side of the display device 10 for the member. Hereinafter, “of the display device 10” is appropriately omitted when the direction is indicated. The two cameras 110 are arranged in the left-right direction of the display device 10, and are disposed to capture the front-surface side of the display device 10. The two display units 120 are arranged in the left-right direction of the display device 10, and are disposed so as to display an image on the rear-surface side of the display device 10.

The display unit 120 displays an image of a virtual space toward the eyes of the user, and thus, the user can feel virtual reality (VR). In a case where the display unit 120 displays a combined image obtained by combining an image (CG) of a virtual object with an image of a real space captured by the camera 110, the user can feel mixed reality (MR). The camera 110 may be used for self-position estimation and space recognition. The cable 160 is connected to an external personal computer (PC) 170, and thus, various kinds of data (information) such as image data to be displayed on the display unit 120 can be transmitted and received between the display device 10 and the PC 170. On a front surface of the housing 100 (front surface of the display device 10) and a side surface of the housing 100 (side surface of the display device 10), inlet and outlet ports 130 for a plurality of fans (not illustrated) to take in and out outside air are provided. The side surface is a surface different from the front surface and the rear surface, and is, for example, a left surface or a right surface.

Note that, an external device connected by using the cable 160 is not limited to the PC 170, and may be a smartphone, a tablet terminal, or the like. In addition, the image data to be displayed on the display unit 120 may be acquired from the external device, or may be generated in the display device 10 (for example, a processing board 140 to be described later). The cable 160 may be connected to an external power supply (battery). In doing so, power supply to the display device 10 can be performed. In this case, various kinds of data (information) such as image data to be displayed on the display unit 120 may be transmitted and received between the display device 10 and the PC 170 by wireless communication.

FIG. 2 is a sectional view of the display device 10 obtained by a surface perpendicular to the up-down direction. The display device 10 includes a plurality of fans 150, the processing board 140, and partitions 151 inside the housing 100. A straight line A indicates an optical axis of the camera 110, and a straight line B (polygonal line) indicates an optical axis of the display unit 120.

The display unit 120 includes display elements 121 and display optical systems 122. Light emitted from a light-emitting surface of the display element 121 is transmitted and reflected by a prism which is the display optical system 122, and is output to an outside (rear-surface side). Note that, the display optical system 122 is not limited to the prism, and may be, for example, a polarization optical system using a polarizing element.

A portion of the straight line B that is the optical axis of the display unit 120, after light is output to the outside, substantially coincides with the straight line A that is the optical axis of the camera 110. In addition, a direction in which the camera 110 captures an outside world is defined as a front-surface side. For example, the straight line A, the straight line B, or both the straight lines are used as axes defining the front-surface side and the rear-surface side. Note that, a portion of the straight line B that is the optical axis of the display unit 120, after light is output to the outside, may not coincide with the straight line A that is the optical axis of the camera 110, may be shifted and deviated with respect to the straight line A, or may be inclined and deviated with respect to the straight line A.

The processing board 140 and the two cameras 110 are disposed on the front-surface side with respect to the two display units 120. For example, as illustrated in FIG. 2, the rear surface (surface on the rear-surface side) of the processing board 140 and the rear surface (surface on the rear-surface side) of each of the two cameras 110 are disposed on the front-surface side with respect to the front surface (surface on the front-surface side) of the display unit 120. In FIG. 2, since the display element 121 is disposed on the front-surface side with respect to the display optical system 122, the front surface of the display unit 120 is the front surface (surface on the front-surface side) of the display element 121. The processing board 140 has a circuit that processes two images captured by the two cameras 110. For example, the processing board 140 performs coordinate conversion processing or the like on the two images captured by the two cameras 110. The two display units 120 display two images based on the two images captured by the two cameras 110, for example, two images processed by the above circuit.

The plurality of fans 150 are disposed on the front-surface side with respect to the processing board 140. For example, as illustrated in FIG. 2, the rear surface (surface on the rear-surface side) of each of the plurality of fans 150 is disposed on the front-surface side with respect to the front surface (surface on the front-surface side) of the processing board 140. The plurality of fans 150 are disposed to cool the processing board 140 serving as a heat source, and performance of the display device 10 can be enhanced (including multifunctional) by providing the plurality of fans 150.

As viewed from the front-surface side, the plurality of fans 150 are disposed between the two cameras 110. In addition, the rear surface (surface on the rear-surface side) of each of the two cameras 110 is disposed on the rear-surface side with respect to the front surface (surface on the front-surface side) of each of the plurality of fans 150. With these dispositions, a thickness (length) of the display device 10 in a front-rear direction (front surface-rear surface direction) can be reduced, and a size of the display device 10 can be decreased. In addition, since the processing board 140 serving as the heat source is disposed in a path of air flowing by the plurality of fans 150, the processing board 140 can be effectively cooled. As a result, it is possible to provide the display device 10 that achieves both decrease in size and high performance (including multi-functionality).

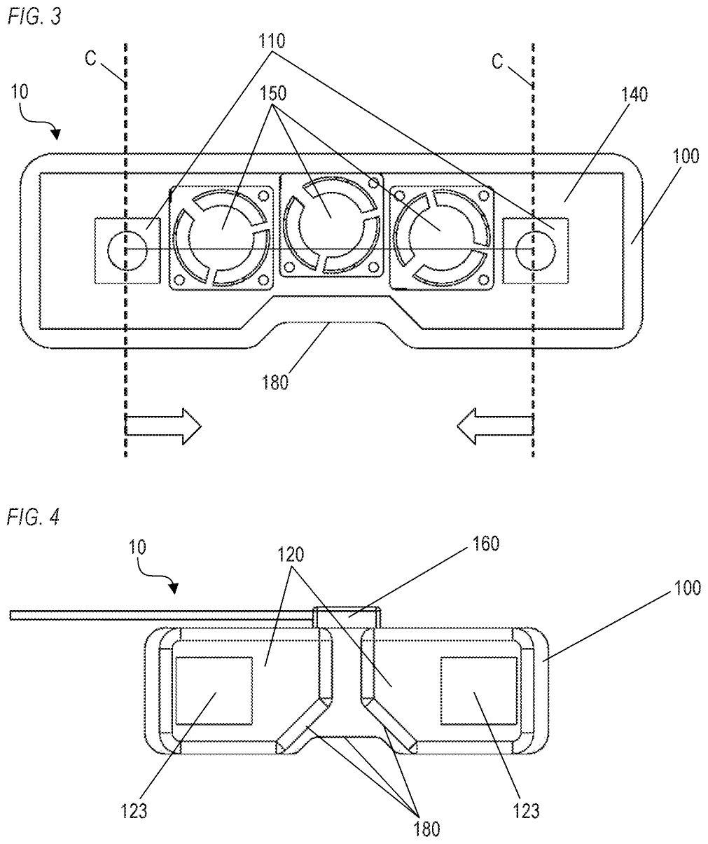

FIG. 3 is a front view illustrating an inside of the display device 10. As described above, the plurality of fans 150 are disposed between the two cameras 110 as viewed from the front-surface side. As illustrated in FIG. 3, a case where the fans are disposed between the two cameras 110 is, for example, a case where the fans are disposed between two surfaces C each passing through a center of the camera 110 and parallel to the up-down direction.

The number of fans 150 is not particularly limited. Among the plurality of fans 150, the fan 150 provided at a central portion of the display device 10 in the left-right direction may be disposed on a top surface side (upper surface side) of the display device 10 with respect to the fan 150 not provided at the central portion. The number of fans 150 provided at the central portion may be one or two or more. In doing so, a space for nose relief 180 of the display device 10 is easily formed. The nose relief 180 is formed in the housing 100, for example.

FIG. 4 is a rear view illustrating an appearance of the display device 10. The nose relief 180 is formed in the housing 100 and the display unit 120, and a window 123 through which the user looks into the displayed image for visual recognition is formed in the display unit 120. The window 123 may or may not be closed (covered) with a transparent member. In a case where the window 123 is not closed by the transparent member, the display optical system 122 is exposed.

As illustrated in FIG. 4, a length of the display device 10 in the up-down direction is substantially equal to a length of each of two display units 120 in the up-down direction. Since components such as the fans 150 are not disposed on the top surface side of the display unit 120, such a configuration is possible, and the decrease in size of the display device 10 can be realized not only in the front-rear direction but also in the up-down direction. Note that, from the viewpoint of ease of holding in a case where the display device 10 is directly gripped, it is preferable that the length of the display device 10 in the up-down direction is not less than 30 mm and not more than 50 mm.

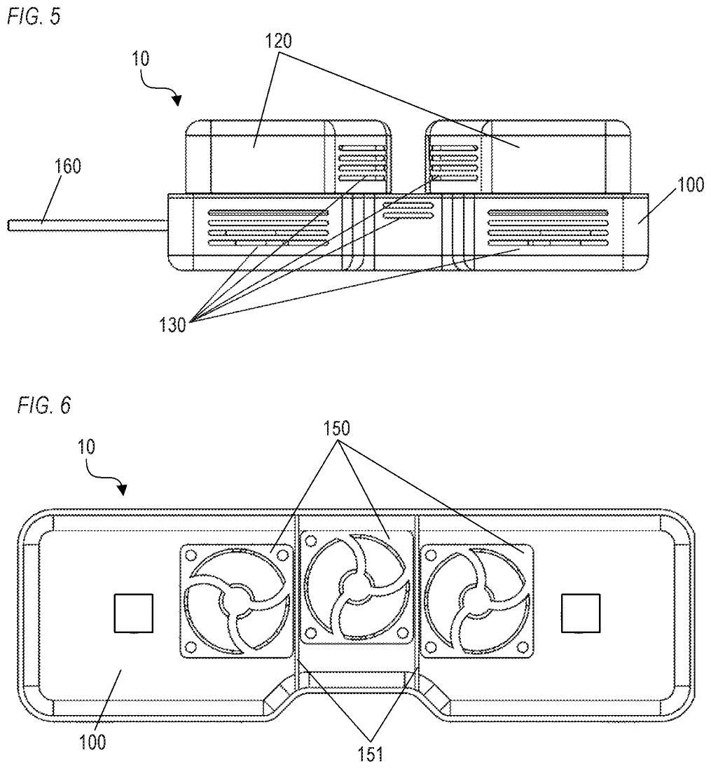

FIG. 5 is a bottom view of the display device 10. A large number of the inlet and outlet ports 130 are provided on a bottom surface side (lower surface side) of the housing 100 and the display unit 120. The inlet and outlet ports 130 are not provided on the top surface of the display device 10. Thus, the risk of contamination from the top surface can be reduced. An interval between the two display units 120 may be changeable in accordance with an eye width of the user (interval between the right eye and the left eye). In this case, it is preferable that the inlet and outlet ports 130 are not hidden by the two display units 120 (a total area of the inlet and outlet ports 130 does not change) such that cooling capability of the plurality of fans 150 does not change even though the interval between the two display units is changed. For example, the inlet and outlet ports 130 may not be provided on the rear surface of the housing 100 (the rear surface of the display device 10) such that the inlet and outlet ports 130 are not hidden by the two display units 120. The inlet and outlet ports 130 may be provided at a central portion or an end portion of the rear surface of the housing 100 such that the inlet and outlet ports 130 are not hidden by the two display units 120.

As illustrated in FIG. 1, the inlet and outlet ports 130 are also provided on the front surface of the display device 10. The plurality of fans 150 are disposed so as to face the inlet and outlet ports 130 provided on the front surface of the display device 10. In order to shorten a distance from the inlet and outlet ports 130 provided in the front surface of the display device 10 to the plurality of fans 150, it is preferable that each of the plurality of fans 150 is an axial fan. In order to suppress exhaust to the face of the user or to increase the area of the inlet port, it is preferable that the inlet and outlet port 130 provided in the front surface of the display device 10 is used as an outlet port, and the inlet and outlet port 130 provided in a surface different from the front surface of the display device 10 is used as an inlet port.

FIG. 6 is a rear view illustrating the inside of the display device 10 (the front-surface side with respect to the processing board 140). In order to improve the cooling capability of the plurality of fans 150, the partitions 151 that separate the plurality of fans 150 from each other may be provided. The partition 151 may be a part of the housing 100 or may be realized by a component different from the housing 100. It is preferable that an end portion on the rear-surface side of the partition 151 extends to approach the processing board 140.

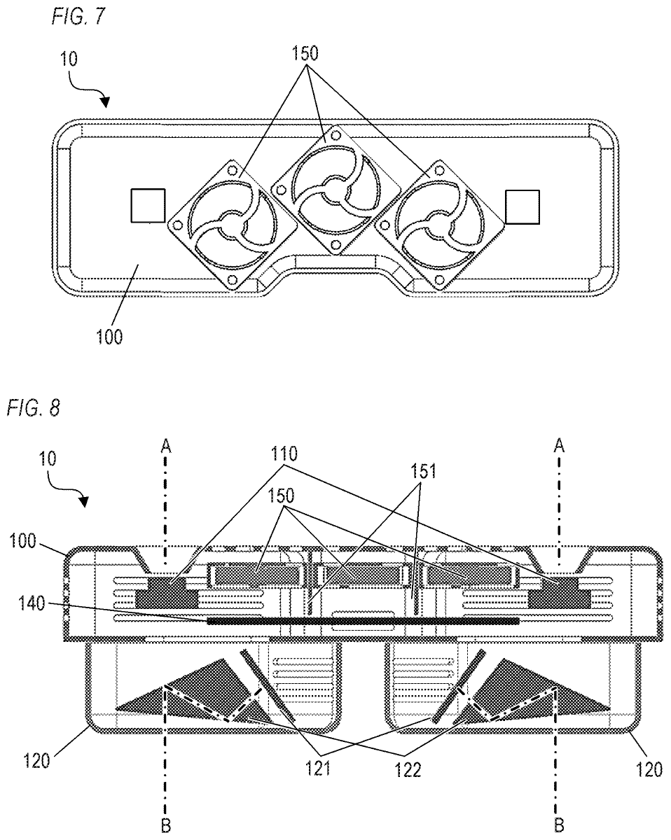

In addition, as illustrated in FIG. 6, each of the plurality of fans 150 has an outline of a quadrangle shape as viewed from the front-surface side. In FIG. 6, in each of the plurality of fans 150, two substantially parallel sides among four sides of the outline (quadrangle) are substantially parallel to the left-right direction of the display device 10, and the remaining two substantially parallel sides are substantially parallel to the up-down direction of the display device 10. The disposition of the fans 150 is not limited to the disposition illustrated in FIG. 6, and may be, for example, the disposition illustrated in FIG. 7. In FIG. 7, each of the plurality of fans 150 is disposed such that two diagonals of the outline (quadrangle) are substantially parallel to the left-right direction and the up-down direction of the display device 10. In doing so, a distance between centers of the plurality of fans 150 can be reduced. Thus, in a case where an element serving as a heat source is disposed at a center of the processing board 140, improvement in exhaust heat efficiency can be expected. In addition, depending on the length of the display device 10 in the up-down direction, it is possible to realize an increase in size of each of the plurality of fans 150 while maintaining a distance between the centers of the two cameras 110, and it is possible to improve the cooling capability.

A heat sink or a heat dissipation fin may be provided on the rear surface (surface on the rear-surface side) of the camera 110, the front surface (surface on the front-surface side) and the rear surface (surface on the rear-surface side) of the processing board 140, and the rear surface (surface on the rear-surface side) of the display element 121, which are heat sources, in accordance with power consumption of the display device 10. However, since a specific gravity of a metal component is high, it is preferable that the amounts (number and size) of the heat sink and the heat dissipation fin are minimized from the viewpoint of decrease in weight of the display device 10. A duct serving as a path of air flowing by the plurality of fans 150 is formed inside the display device 10, and the heat sink and the heat dissipation fin are brought close to the inlet and outlet ports 130. As a result, the improvement in exhaust heat efficiency can be expected.

FIG. 8 is a modification of the sectional view of the display device 10 obtained by the surface perpendicular to the up-down direction. As illustrated in FIG. 8, a length of the processing board 140 in the left-right direction may be shortened, and the two cameras 110 may be brought close to the display unit 120. For example, the front surface (surface on the front-surface side) of each of the two cameras may be disposed on the rear-surface side with respect to the front surface (surface on the front-surface side) of each of the plurality of fans 150. In doing so, it is possible to further decrease the size of the display device 10 also in the front-rear direction.

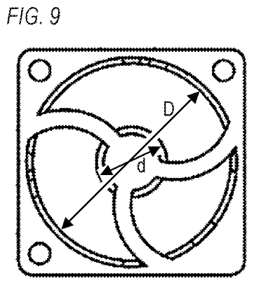

Since the display device 10 is used in proximity to the face, it is preferable that each of the plurality of fans 150 is a silent fan having a low rotation speed. However, the cooling capability of the silent fan is relatively low. Thus, it is preferable that a total area of the inlet and outlet ports 130 of the display device 10 is large. Specifically, it is preferable that the total area of the inlet and outlet ports 130 is ⅓ or more of a total area of annular regions of the plurality of fans 150. The annular region is a region where blades are formed and air passes through as viewed in parallel with a rotation axis of the fan 150. FIG. 9 is a diagram illustrating the fan 150, and the fan 150 has a rotation axis in a direction perpendicular to a paper surface of FIG. 9. In FIG. 9, a blade extending from a position of a diameter d (inner diameter) around the rotation axis to a position of a diameter D (outer diameter) is formed. In this case, the annular region of one fan can be calculated by (D²−d²)π/4.

As described above, according to the present embodiment, it is possible to provide a display device that achieves both decrease in size and high performance (including multi-functionality).

Note that, although the embodiments of the present disclosure have been described in detail, the present disclosure is not limited by these specific embodiments. Various forms in the range without departing from the gist of the disclosure shall also be encompassed by the present disclosure. Further, the above-described embodiments merely illustrate embodiments of the present disclosure, and the embodiments can be combined as necessary.

According to the present disclosure, it is possible to provide a display device such as an HMD that achieves both decrease in size and high performance (including multi-functionality).

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2024-158197, filed Sep. 12, 2024, which is hereby incorporated by reference herein in its entirety.

What is claimed is:

1. A display device comprising:
two cameras that are arranged in a left-right direction of the display device and capture a front-surface side of the display device;
a processing board;
two displays that are arranged in the left-right direction and display images on a rear-surface side of the display device;
a plurality of fans; and
one or more inlet and outlet ports,
wherein the processing board and the two cameras are disposed on the front-surface side with respect to the two displays,
the plurality of fans are disposed on the front-surface side with respect to the processing board,
the plurality of fans are disposed between the two cameras as viewed from the front-surface side, and
a surface, on the rear-surface side, of each of the two cameras is disposed on the rear-surface side with respect to a surface, on the front-surface side, of each of the plurality of fans.

2. The display device according to claim 1, wherein the two displays display two images based on two images captured by the two cameras.

3. The display device according to claim 1, wherein the processing board processes two images captured by the two cameras.

4. The display device according to claim 1, wherein the plurality of fans cools the processing board.

5. The display device according to claim 1, wherein a length of the display device in an up-down direction is substantially equal to a length of each of the two displays in an up-down direction.

6. The display device according to claim 1, wherein a length of the display device in an up-down direction is not less than 30 mm and not more than 50 mm.

7. The display device according to claim 1, wherein each of the plurality of fans is an axial fan.

8. The display device according to claim 1, wherein, among the plurality of fans, a fan provided at a central portion of the display device in the left-right direction is disposed on a top surface side of the display device with respect to a fan not provided at the central portion.

9. The display device according to claim 1, further comprising
one or more partitions that separate the plurality of fans from each other.

10. The display device according to claim 1, wherein the one or more inlet and outlet ports are provided on a surface different from a top surface of the display device.

11. The display device according to claim 1,
wherein an interval between the two displays is changeable, and
the one or more inlet and outlet ports are not hidden by the two displays even though an interval between the two displays is changed.

12. The display device according to claim 1, wherein the one or more inlet and outlet ports are provided on a front surface of the display device.

13. The display device according to claim 1, wherein the one or more inlet and outlet ports include an outlet port provided on a front surface of the display device and an inlet port provided on a surface different from the front surface of the display device.

14. The display device according to claim 1,
wherein each of the plurality of fans has an annular region in which a blade is formed and through which air passes as viewed in parallel with a rotation axis of the fan, and
a total area of the one or more inlet and outlet ports is ⅓ or more of a total area of the annular regions of the plurality of fans.

15. The display device according to claim 1, wherein a surface, on the front-surface side, of each of the two cameras is disposed on the rear-surface side with respect to a surface, on the front-surface side, of each of the plurality of fans.

16. The display device according to claim 1,
wherein, as viewed from the front-surface side,
each of the plurality of fans has an outline of a quadrangle, and
each of the plurality of fans is disposed such that two diagonals of the quadrangle are substantially parallel to the left-right direction and an up-down direction of the display device.
